(19) United States
(12) Patent Application Publication
(10) Pub. No.: US 2012/0170224 A1
(43) Pub. Date: Jul. 5, 2012

(54) CIRCUIT BOARD FRAME WITH INTEGRAL HEAT SINK FOR ENHANCED THERMAL TRANSFER

(75) Inventors: Michael Lee Fowler, Minoa, NY (US); Andrew Jonathan Brindle, Clay, NY (US)

(73) Assignee: SRC, INC., North Syracuse, NY (US)

(21) Appl. No.: 12/980,726

(22) Filed: Dec. 29, 2010

(51) Int. Cl. H05K 7/20

(52) U.S. Cl. 361/720

(57) ABSTRACT

A circuit board frame and a circuit board assembly that includes the circuit board frame includes a first region designed for receiving a circuit board, and a second region contiguous with the first region and including a heat sink. The circuit board frame and circuit board assembly are designed and fabricated so that the first region is located inside a circuit board chassis and the heat sink is located outside the circuit board chassis when the circuit board frame or the circuit board assembly is assembled into the circuit board chassis by insertion into at least one slot within a sidewall of the circuit board chassis. The at least one slot within the sidewall of the circuit board chassis may have straight sidewalls, or alternatively tapered sidewalls that may ease insertion and assembly of the circuit board frame or circuit board assembly into the circuit board chassis. Protrusion of the heat sink, which is contiguous with the first region, through the circuit board chassis sidewall improves thermal transfer efficiency from a circuit board to the heat sink in-part via reduction of thermal transfer inhibiting interfaces.

### BACKGROUND

1. Field of the Invention

The invention relates generally to thermal transfer within circuit board assemblies. More particularly, the invention relates to enhanced thermal transfer within circuit board assemblies.

2. Description of the Related Art

In order to effectively realize enhanced functionality of advanced microelectronic circuits, circuit components that comprise those advanced microelectronic circuits are typically assembled to a circuit board. Such a circuit board typically further comprises a plurality of conductor layers that is separated by a plurality of dielectric layers so that a plurality of circuit components may be electrically interconnected. To provide further advanced functionality, individual circuit boards (which are often designated as “daughter boards”) may be further connected and interconnected using a backplane (which is often designated as a “motherboard”).

Finally, for purposes of environmental protection, as well as to facilitate proper assembly of a plurality of circuit boards with respect to a backplane, both the backplane and the plurality of circuit boards are positioned and assembled with respect to each other using a chassis that may also function as an environmental enclosure.

While the use of such a chassis or environmental enclosure is common within the electronics packaging and component assembly art, the use of such a chassis or environmental enclosure is not entirely without problems. In that regard, considerable heat is often generated from circuit boards and electrical components assembled thereto, and to that end efficient transfer and dissipation of that generated heat within a chassis or environmental enclosure may often provide difficulties.

Various thermal transfer apparatus or thermal dissipation apparatus are known in the circuit board design, fabrication and assembly art for use within the context of thermal transfer or thermal dissipation of heat from circuit boards and environmental enclosures.

For example, Van Asten, in U.S. Pat. No. 4,916,575, teaches a multiple circuit board module with enhanced thermal transfer. The multiple circuit board module uses a plurality of thermally conductive support planes, and a thermally conductive frame, for thermal transfer and thermal dissipation.

In addition, Jacob et al., in U.S. Pat. No. 5,272,593, teaches another circuit board enclosure with enhanced thermal transfer and thermal dissipation. This particular circuit board enclosure uses a cooling frame interposed between a heat generating electrical component and a circuit board.

Finally, Habing et al., in U.S. Pat. No. 6,246,582, teaches a circuit board assembly providing enhanced thermal transfer. To effectuate the foregoing result, this particular circuit board assembly uses a wedge-lock assembly having an increased cross-sectional dimensional size.

Desirable are circuit board assemblies, and related circuit board components that comprise those circuit board assemblies, having enhanced thermal transfer capabilities and enhanced thermal dissipation capabilities.

### SUMMARY OF THE INVENTION

The invention provides a circuit board frame, a circuit board assembly that includes the circuit board frame and a circuit board chassis into which may be assembled the circuit board frame and the circuit board assembly. The circuit board frame includes a first region designed to receive a circuit board (i.e., a region to which a circuit board is assembled). The circuit board frame also includes contiguous with the first region at least one second region that comprises a heat sink. By using such a circuit board frame or a circuit board assembly that includes the circuit board frame, the invention provides for enhanced thermal transfer and enhanced thermal dissipation since the circuit board frame includes a heat sink within at least one second region contiguous with a first region designed for receiving a circuit board, and thus the circuit board frame may be fabricated absent components that provide thermal transfer inhibiting interfaces or barriers interposed between the first region and the second region within the circuit board frame.

A circuit board chassis into which may be assembled a circuit board frame or a circuit board assembly in accordance with the invention includes two pair of counter-opposed sidewalls that are connected to form an enclosure (i.e., typically rectangular), where at least one of the sidewalls includes a slot that begins at the top of the sidewall, but does not continue to the bottom of the sidewall. The slot is designed to accommodate the circuit board frame or the circuit board assembly in accordance with the invention in a fashion such that: (1) the first region of the circuit board frame or circuit board assembly (i.e., the region designed for receiving the circuit board) is interior to the circuit board chassis; and (2) the contiguous second region of the circuit board frame or circuit board assembly (i.e., the region which includes the heat sink) is exterior to the circuit board chassis, when a circuit board frame or a circuit board assembly is assembled into the circuit board chassis. To that end also included within an interior of the sidewall of the circuit board chassis may be a plurality of ribs that are separated by the slot. Finally, the slot may be tapered with a greater width at the top of the sidewall than at a location nearer the bottom of the sidewall, to facilitate insertion of the circuit board frame or circuit board assembly into the circuit board chassis.

A particular circuit board frame in accordance with the invention includes a first region designed to receive a circuit board. This particular circuit board frame also includes at least one second region contiguous with the first region and including a heat sink.

A particular circuit board assembly in accordance with the invention includes a circuit board frame comprising: (1) a first region designed to receive a circuit board; and (2) at least one second region contiguous with the first region and including a heat sink. This particular circuit board assembly also includes a circuit board assembled to the first region of the circuit board frame.

A particular circuit board chassis in accordance with the invention includes a first sidewall and a second sidewall that are counter-opposed, and separated by and connected to a third sidewall and a fourth sidewall that are counter-opposed, and separated by and connected to the first sidewall and the second sidewall. Within this particular circuit board chassis at least one of the first sidewall, the second sidewall, the third sidewall and the fourth sidewall includes therein a slot that begins at a top of the sidewall but does not reach a bottom of the sidewall.

### BRIEF DESCRIPTION OF THE DRAWINGS

The objects, features and advantages of the embodiments are understood within the context of the Description of the Preferred Embodiments, as set forth below. The Description of the Preferred Embodiments is understood within the context of the accompanying drawings, that form a material part if this disclosure, wherein:

FIG. 1 shows a schematic end-view diagram of a circuit board frame in accordance with a particular embodiment positioned separated with respect to a circuit board.

FIG. 2 shows a schematic end-view diagram of the circuit board frame of FIG. 1 having assembled thereto the circuit board of FIG. 1 to provide a circuit board assembly further assembled into a circuit board chassis which is not completely illustrated.

FIG. 3 shows a schematic isometric-view diagram of the circuit board assembly in accordance with FIG. 2 absent the circuit board chassis which is not illustrated.

FIG. 4 shows a schematic isometric-view diagram of a circuit board chassis into which may be assembled a circuit board frame or a circuit board assembly in accordance with the embodiments.

FIG. 5 shows, in accordance with FIG. 2, a schematic isometric-view diagram of the circuit board chassis of FIG. 4 into which has been assembled the circuit board assembly of FIG. 3 which includes the circuit board frame of FIG. 1.

### DESCRIPTION OF THE PREFERRED EMBODIMENTS

The embodiments, which include a particular circuit board frame, a particular circuit board assembly and a particular circuit board chassis, are understood within the context of the description set forth below. The description set forth below is understood within the context of the drawings described above. Since the drawings are intended for illustrative purposes, the drawings are not necessarily drawn to scale.

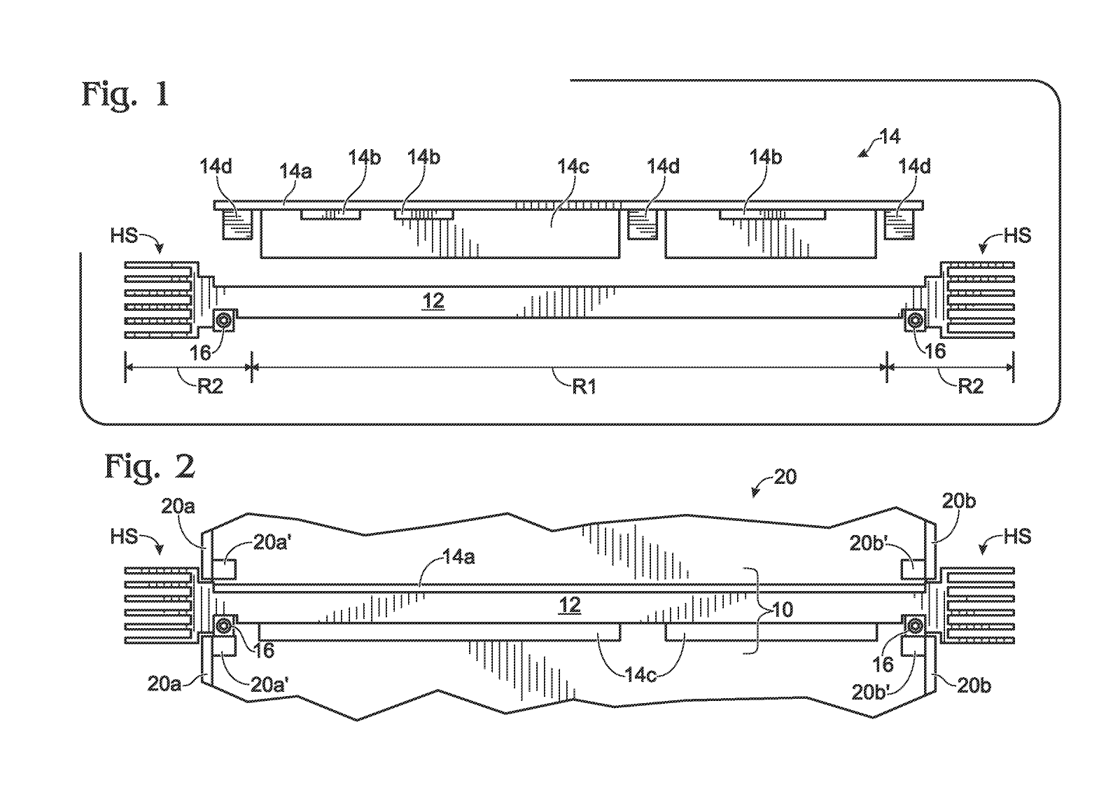

FIG. 1 shows a schematic end-view diagram of a circuit board frame in accordance with an illustrative non-limiting embodiment of the invention spatially separated from a circuit board.

FIG. 1 shows a circuit board frame 12 that includes a first central region R1 that is contiguous with and separates two second distal end regions R2.

The first central region R1 of the circuit board frame 12 includes an aperture (which is illustrated in greater detail within a schematic perspective-view diagram that follows) which assists in positioning, receiving and assembling to the circuit board frame 12 a circuit board 14 that is also illustrated in FIG. 1. The two second distal end regions R2 of the circuit board frame 12 each include an integral heat sink HS that further includes at least one fin and preferably at least two fins (i.e., illustrated in particular as six fins). As is illustrated in FIG. 1, the fin(s) that comprise the heat sink HS extend outwardly from the first central region R1 of the circuit board frame 12 in a direction parallel to the plane of the circuit board 14 when positioned, received and assembled to the circuit board frame 12.

While within FIG. 1 the fins that comprise the heat sink HS are shown to extend outwardly in a direction parallel to the plane of the circuit board 14, this particular disposition of the fins is intended as a non-limiting embodiment, for illustrative purposes. To that end, the embodiments in general also contemplate other fin geometries and locations for a heat sink (i.e., such as the heat sinks HS), such fin geometries and locations including but not limited to radial shaped, pin shaped and wavy shaped fin geometries and locations.

Finally, FIG. 1 illustrates a plurality of wedge-lock assemblies 16 located assembled to the circuit board frame 12 at the locations of the transitions from: (1) the first central region R1 of the circuit board frame 12 that is designed to receive the circuit board 14; with (2) the two second distal end regions of the circuit board frame 12 that comprise the heat sinks HS.

The circuit board frame 12 is intended to provide physical and mechanical support to the circuit board 14, as well as to provide a pathway for thermal transfer and thermal dissipation from the circuit board 14. To that end, the circuit board frame 12 often comprises, and is fabricated from, a metal material, such as but not limited to an iron, iron alloy, stainless steel, stainless steel alloy, aluminum, aluminum alloy, copper, copper alloy, titanium or titanium alloy metal thermal conductor material. When weight savings may be a particularly important consideration, the circuit board frame 12 may alternatively also include conductive composites such as but not limited to carbon fiber composites.

As is illustrated in FIG. 1 with respect to the circuit board frame 12, the first central region R1 is intended as contiguous with each of the two second distal end regions R2. Thus, the embodiment intends that the circuit board frame 12 includes no thermal transfer inhibiting interfaces or barriers interposed between the first central region R1 of the circuit board frame 12 and the two second distal end regions R2 of the circuit board frame 12. To that end, the circuit board frame 12 may be fabricated from a single piece of thermal transfer material that is machined, cast, extruded or otherwise fashioned so that no thermal transfer inhibiting interfaces or barriers are present or formed interposed between the first central region R1 of the circuit board frame 12 and the two second distal end regions R2 of the circuit board frame 12.

The circuit board 14 and the wedge-lock assemblies 16 are otherwise generally conventional in the circuit board design, manufacture and assembly art.

In particular, and as illustrated in FIG. 1, the circuit board 14 comprises several components that include, but are not necessarily limited to: (1) a circuit board substrate 14a as a base substrate upon which other circuit board 14 components are assembled; (2) a plurality of electrical components 14b assembled to the circuit board substrate 14a; (3) a plurality of electrical connectors 14c also assembled to the circuit board substrate 14a to assure electrical connection to the plurality of electrical components 14b; and (4) a plurality of alignment sockets 14d also assembled to the circuit board substrate 14a to provide for proper alignment of the electrical connectors 14c to mating electrical connectors.

The circuit board substrate 14a may comprise any type of circuit board substrate that is otherwise generally conventional or alternatively non-conventional, in the circuit board and electrical component fabrication and assembly art. Typically, the circuit board substrate 14a will include multiple levels and layers comprising patterned conductor layers that are separated by dielectric layers. Typically, the patterned conductor layers comprise conductor materials such as but not limited to aluminum, aluminum alloy, copper and copper alloy conductor materials. Typically, the dielectric layers comprise resin impregnated dielectric materials such as but not limited to fiberglass matting materials.

The electrical components 14b that are assembled to the circuit board substrate 14a may include, but are not necessarily limited to resistors, capacitors, diodes and transistors as discrete electrical components that are assembled individually to the circuit board substrate 14a. Such electrical components 14b may also include modules that further comprise the foregoing individual discrete electrical components, or multiple discrete electrical components that provide circuits that are derived from the foregoing discrete electrical components.

The electrical connectors 14c and the alignment sockets 14d are discussed in greater detail below within the context of description of a schematic perspective-view diagram that includes the circuit board frame 12 and the circuit board 14.

The wedge-lock assemblies 16, as will be illustrated in greater detail within the context of another schematic end-view diagram that follows, are intended to provide a means for clamping the circuit board frame 12 with or without the circuit board 14 assembled thereto, into a circuit board chassis that will be illustrated in further detail. Thus, the wedge-lock assemblies 16 are otherwise generally conventional in the circuit board design, fabrication and assembly art. To that end, the wedge-lock assemblies 16 typically comprise counter-opposed wedge shaped elements which when drawn to each other by a lineal contracting force will offset in a fashion such that they wedge the circuit board frame 12 into place within the sidewalls of a circuit board chassis that will be illustrated in further detail within the context of another schematic end-view diagram that is described in greater detail below.

Typically, each of the wedge-lock assemblies 16 is fitted into a corresponding notch within the circuit board frame 12 at the location of the transition from the first central region R1 to which is received and assembled the circuit board 14 to the two second distal end regions R2 that include the heat sinks HS. Typically and preferably, each of the notches has width dimensions that correspond with width dimensions of the wedge-lock assemblies 16, that in turn range from about 6 to about 12 millimeters.

FIG. 2 first shows the results of assembly of the circuit board 14 of FIG. 1 into the circuit board frame 12 of FIG. 1 to provide a circuit board assembly 10. As is illustrated within the schematic end-view diagram of FIG. 2, the circuit board 14 is assembled to the circuit board frame 12 so that the circuit board substrate 14a is received on an opposite side of the circuit board frame 12 in comparison with the wedge-lock assemblies 16. As a result of such an assembly of the circuit board frame 12 and the circuit board 14, the electrical connectors 14c protrude through and are exposed at the side of the circuit board frame to which the wedge-lock assemblies 16 are assembled. The electrical components 14b and the alignment sockets 14d, which have a narrower profile in comparison with the electrical connectors 14c, are obscured beneath the circuit board frame 12 and are thus not otherwise observable in FIG. 2.

FIG. 2 also shows the results of assembly and installation of the circuit board frame 12 including the circuit board 14 (i.e., in an aggregate now designated as the circuit board assembly 10), into a pair of opposing sidewalls 20a and 20b of a circuit board chassis 20 that is generally illustrated in FIG. 2, but not otherwise completely illustrated in FIG. 2. As is illustrated within the schematic end-view diagram of FIG. 2, the circuit board assembly 10 that comprises the circuit board frame 12 and the circuit board 14 is assembled and fastened in place within the pair of opposing sidewalls 20a and 20b of the circuit board chassis 20 by means of the pair of wedge-lock assemblies 16 that wedge the circuit board frame 12 and the circuit board substrate 14a into a corresponding pair of ribs 20a′ or 20b′ that are connected to interior portions of the opposing sidewalls 20a or 20b of the circuit board chassis 20. As is illustrated in FIG. 2, the first central region R1 of the circuit board frame 12, including the circuit board 14, is located and assembled inside the circuit board chassis 20, while the two second distal end regions R2 of the circuit board frame 12 including the heat sinks HS, are located and assembled outside the circuit board chassis 20.

The circuit board chassis 20 whose opposing sidewalls 20a and 20b are illustrated in FIG. 2 will be illustrated in further detail within the context of a schematic isometric-view diagram that follows.

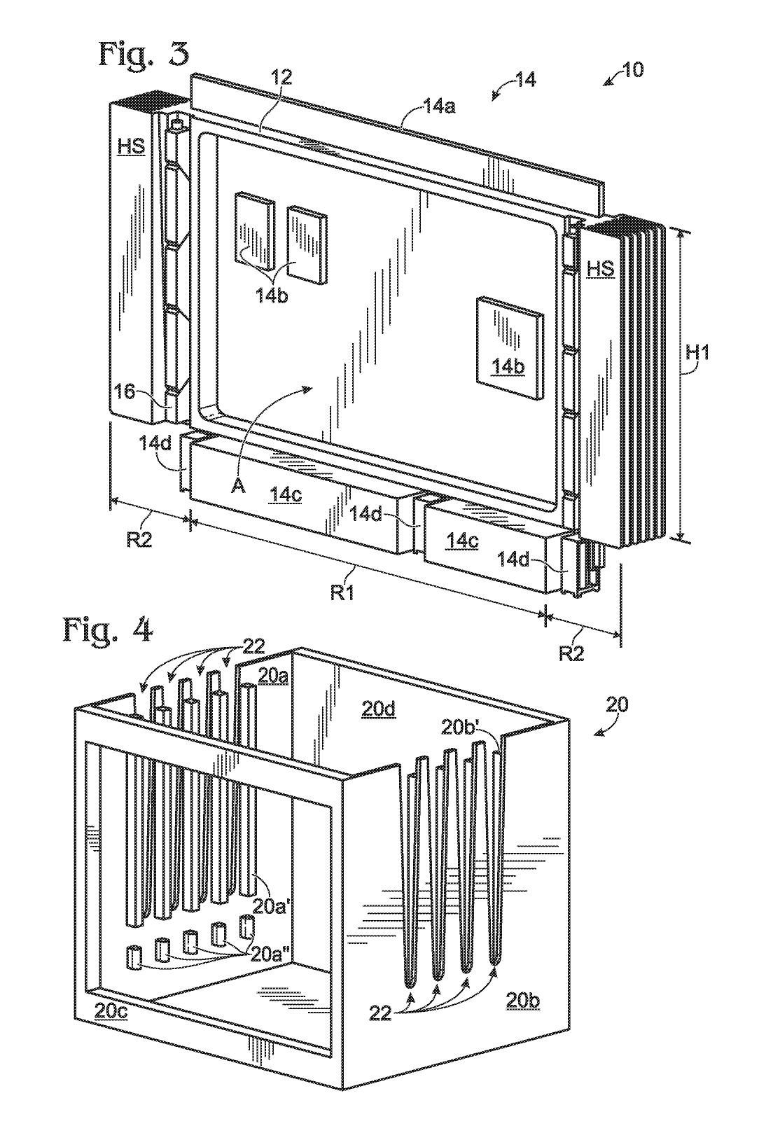

FIG. 3 shows a schematic isometric-view diagram of the circuit board assembly 10 in accordance with FIG. 2, absent the circuit board chassis 20.

FIG. 3 shows the circuit board frame 12 to which is assembled the circuit board 14 that includes the circuit board substrate 14a, the electrical components 14b, the electrical connectors 14c and the alignment sockets 14d. As is illustrated in FIG. 3, the circuit board frame 12 includes an aperture A within the first central region R1 of the circuit board frame 12. The aperture A assists in positioning, receiving and assembly of the circuit board 14 with respect to the circuit board frame 12.

While the aperture A as illustrated in FIG. 3 is illustrated as penetrating completely through the first central region R1 of the circuit board frame 12 to provide a view of the underlying electrical components 14b such a completely penetrating aperture is not intended as limiting the embodiments. Rather, the embodiments also contemplate that the circuit board frame 12 may alternatively be comprised of a solid uninterrupted conductor material in the first central region R1 of the circuit board frame 12 to better facilitate heat transfer from the circuit board substrate 14a and the electrical components 14b assembled to the circuit board substrate 14a to the heat sinks HS within the two second distal end regions R2 of the circuit board frame 12.

Also illustrated in FIG. 3 are the heat sinks HS that comprise the two second distal end regions R2 of the circuit board frame 12 and which are parallel with side portions of the circuit board 14.

As is illustrated within the schematic isometric-view diagram of FIG. 3, the heat sinks HS within the circuit board frame 12 encompasses a height H1 less than the height of the circuit board 14 (i.e., or circuit board substrate 14a), and the heat sinks HS are positioned along opposite edges of the circuit board 14. Such a height H1, as illustrated in FIG. 3, is typically from about 15 to 30 centimeters. A particular width of the circuit board 14 generally corresponds with the width of the first central region R1 of the circuit board frame 12, that is typically from about 10 to about 30 centimeters.

Also illustrated within the schematic isometric-view diagram of FIG. 3 is the pair of wedge-lock assemblies 16 assembled to the circuit board frame 12 at the transitions of the first central region R1 region with the two second distal end regions R2.

FIG. 3 also shows the plurality of alignment sockets 14d intended to mate with a corresponding plurality of alignment pins located and assembled to a backplane (i.e., motherboard) to which the circuit board assembly 10 that is illustrated in FIG. 3 is intended to be assembled. Finally, FIG. 3 shows the plurality of electrical connectors 14c located and assembled to the circuit board substrate 14a at a base region of the circuit board assembly 10 and intended to mate with a plurality of connectors that are located and assembled on the backplane to which is located and assembled the alignment pins that are intended to register with the alignment sockets 14d.

Each of the foregoing alignment sockets 14d and electrical connectors 14c is otherwise generally conventional in the circuit board design, assembly and fabrication art.

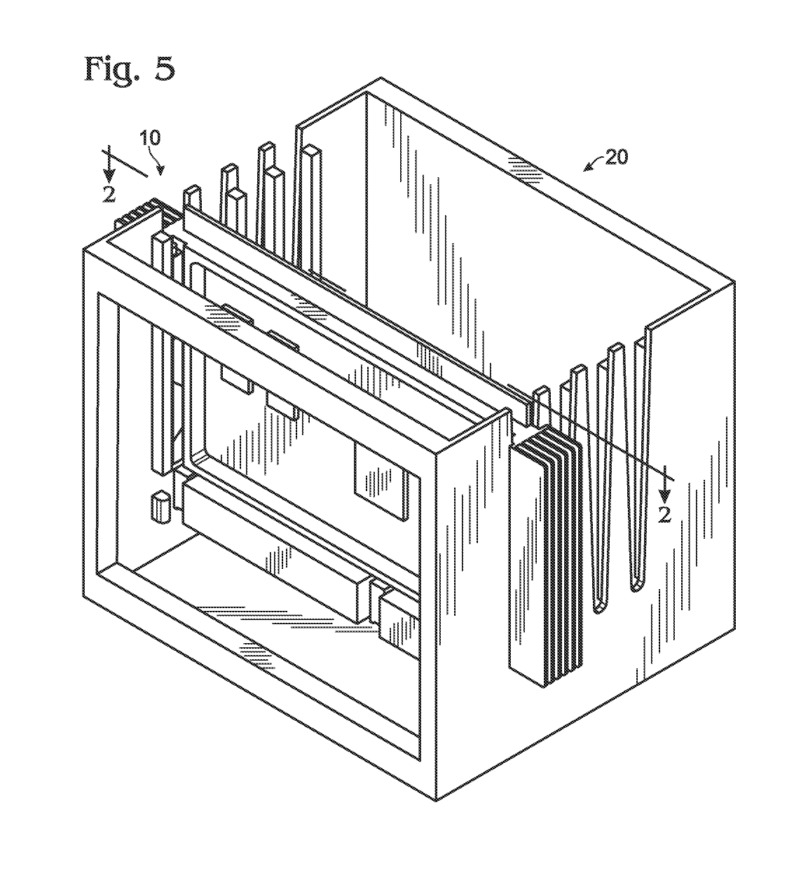

FIG. 4 shows a schematic isometric-view diagram of the circuit board chassis 20 that is generally, and incompletely, illustrated in the schematic end-view diagram of FIG. 2. As is illustrated within FIG. 4, the circuit board chassis 20 includes a plurality of sidewalls, arranged in counter-opposed pairs (i.e., 20a and 20b, as well as 20c and 20d) that are further separated by and connected to the other counter-opposed pair of sidewalls. A first sidewall 20a and a second sidewall 20b include a plurality of slots 22 to accommodate a circuit board assembly 10 in accordance with the particular embodiments as illustrated above. As is illustrated within the schematic cross-sectional diagram of FIG. 4, the slots 22 begin at a top of the sidewall 20a or 20b and do not extend to a bottom of the sidewall 20a or 20b.

Although slots, such as the plurality of slots 22, are not limited to any particular dimensions, FIG. 4 shows in particular the slots 22 that include a tapered dimension with a wider slot dimension at a top of the sidewall 20a or 20b and a narrower slot dimension nearer the bottom of the sidewall 20a or 20b. Nonetheless, the plurality of slots 22 as illustrated in FIG. 4 is intended to include straight sidewall slots that are further intended to accommodate the circuit board assembly 10 of FIG. 2 that may also generally have a straight profile.

The tapered sidewall slot 22 dimensional sizing that is illustrated in FIG. 4 includes a taper from about 0.5 to about 2.0 degrees with respect to straight and vertical sidewall slots. Such a tapered sidewall slot 22 allows for ease of assembly and proper gasketing of the tapered sidewall slot 22 under circumstances where the circuit board chassis 20 may desirably be environmentally secure from local environmental contaminants.

FIG. 4 also illustrates a plurality of supports 20a″ located and formed (or assembled) on the interior of sidewall 20a of the circuit board chassis 20, in addition to the plurality of ribs 20a′. Such a plurality of supports 20a″ is intended to support a backplane that will not otherwise be illustrated.

FIG. 5 shows a schematic isometric-view diagram of the circuit board chassis 20 of FIG. 4 into which now is located and assembled the circuit board assembly 10 whose schematic isometric view diagram is illustrated in FIG. 3, as is further consistent with the schematic end-view diagram of FIG. 2.

As is illustrated within the schematic isometric-view diagram of FIG. 5, the circuit board assembly 10 is located and assembled within the circuit board chassis 20 so that the heat sinks HS within the two second distal end regions R2 of the circuit board frame 12 extend to the outside of the circuit board chassis 20, while the first central region R1 of the circuit board frame 12 that is designed to receive (and has assembled thereto) the circuit board 14 is contained with the inside of the circuit board chassis 20. Thus, within the context of the instant particular and non-limiting embodiment, a first aspect of thermal transfer efficiency from the circuit board 14 to the environment that surrounds the circuit board chassis 20 is effected by fabricating a heat sink HS integrally to and contiguously with a circuit board frame 12 absent any thermal transfer inhibiting interface or component to provide a low thermal loss pathway for thermal transfer from the circuit board 14 and through the circuit board frame 12 and ultimately to the heat sink HS. In a second instance, a second aspect of thermal transfer efficiency from the circuit board 14 in accordance with the embodiments is effected by penetrating the heat sinks HS that are integral and contiguous with the circuit board frame 12 through a sidewall of the circuit board chassis 20 rather than abutting a circuit board to an inner sidewall of a circuit board chassis, and further assembling a heat sink upon an outer sidewall of the circuit board chassis located near the abutment of the circuit board near the inner sidewall of the circuit board chassis.

The embodiments of the invention as described above are illustrative of the invention rather than limiting of the invention. Revisions and modifications may be made to materials, structures and dimensions of a circuit board frame, a circuit board assembly and a circuit board chassis in accordance with the embodiments, while still providing a circuit board frame, a circuit board assembly or a circuit board chassis in accordance with the invention, further in accordance with the accompanying claims.

What is claimed is:

1. A circuit board frame comprising:
a first region designed to receive a circuit board; and
at least one second region contiguous with the first region and including a heat sink.

2. The circuit board frame of claim 1 wherein the first region and the second region are contiguous absent a thermal transfer inhibiting interface interposed between the first region and the second region.

3. The circuit board frame of claim 1 wherein the heat sink includes at least one cooling fin that extends outward from the first region in a direction parallel to a plane of the circuit board when received and assembled to the first region.

4. The circuit board frame of claim 1 wherein the circuit board has a width dimension from about 10 to about 30 centimeters and a height dimension from about 15 to about 30 centimeters.

5. The circuit board frame of claim 1 wherein the first region and the second region are contiguous along a side of the circuit board.

6. The circuit board frame of claim 1 wherein the first region is contiguous with two second regions along a pair of opposite sides of the circuit board.

7. The circuit board frame of claim 1 further comprising at least one wedge-lock assembly assembled to the circuit board frame at the transition from the first region to the second region.

8. The circuit board frame of claim 1 further comprising at least one notch in the circuit board frame at the transition from the first region to the second region.

9. A circuit board assembly comprising:
a circuit board frame comprising:
a first region designed to receive a circuit board;
at least one second region contiguous with the first region and including a heat sink; and
a circuit board assembled to the first region.

10. The circuit board assembly of claim 9 wherein the first region and the second region are contiguous absent a thermal transfer inhibiting interface interposed between the first region and the second region.

11. The circuit board assembly of claim 9 wherein the heat sink includes at least one cooling fin that extends outward from the first region in a direction parallel to a plane of the circuit board.

12. The circuit board assembly of claim 9 wherein the first region and the second region are contiguous along a side of the circuit board.

13. The circuit board assembly of claim 9 wherein the first region is contiguous with two second regions along a pair of opposite sides of the circuit board.

14. The circuit board assembly of claim 9 further comprising at least one wedge-lock assembly assembled to the circuit board frame at a transition between the first region and the second region.

15. A circuit board chassis comprising:
a first sidewall and a second sidewall that are counter-opposed, and separated by and connected to a third sidewall and a fourth sidewall that are counter-opposed, and separated by and connected to the first sidewall and the second sidewall, wherein at least one of the first sidewall, the second sidewall, the third sidewall and the fourth sidewall includes therein at least one slot that begins at a top of the sidewall but does not reach a bottom of the sidewall.

16. The circuit board chassis of claim 15 wherein the slot has straight sidewalls.

17. The circuit board chassis of claim 15 wherein the slot has tapered sidewalls.

18. The circuit board chassis of claim 17 wherein the tapered sidewalls have a taper from about 0.5 to about 2.0 degrees to provide a top of the slot wider than a bottom of the slot.

19. The circuit board chassis of claim 17 further comprising a circuit board frame fitted into the slot wherein:
a first region of the circuit board frame designed to receive a circuit board is located in the interior region of the circuit board chassis; and
a second region of the circuit board frame contiguous with the first region that includes a heat sink is located exterior to the circuit board chassis.

20. The circuit board chassis of claim 19 further comprising a circuit board assembled to the first region of the circuit board frame.
